(19) United States
(12) Patent Application Publication
(10) Pub. No.: US 2026/0334004 A1
(43) Pub. Date: Oct. 22, 2026

(54) DISPLAY DEVICE AND METHOD FOR FABRICATING THE SAME

(71) Applicant: Samsung Display Co., Ltd., Yongin-si (KR)

(72) Inventors: Dong Hyun LEE, Yongin-si (KR); Youn Woong KANG, Yongin-si (KR); Min Sang KOO, Yongin-si (KR)

(73) Assignee: Samsung Display Co., Ltd., Yongin-si (KR)

(21) Appl. No.: 19/381,751

(22) Filed: Nov. 6, 2025

(30) Foreign Application Priority Data
Apr. 16, 2025 (KR) 10-2025-0049608

(51) Int. Cl. H10K 59/121; H10K 59/40

(52) U.S. Cl. CPC H10K 59/1213; H10K 59/40

(57) ABSTRACT

A display device includes a first substrate including a display area and a non-display area, and a thin-film transistor layer on the first substrate and including an insulating layer on the first substrate, and a first back connection electrode on the insulating layer. The display device includes an emission material layer on the thin-film transistor layer, a filling member on the insulating layer and the first back connection electrode and on an outer side of the emission material layer, a second substrate on the emission material layer and the filling member, a touch connection pad on the second substrate, and a touch connection line on the touch connection pad and the second substrate and along outermost sides of the second substrate, the filling member and the thin-film transistor layer and on an outermost side of the first substrate and overlapping with the first back connection electrode.

### CROSS-REFERENCE TO RELATED APPLICATIONS

This U.S. non-provisional application claims priority under 35 U.S.C. § 119 to Korean Patent Application No. 10-2025-0049608, filed on Apr. 16, 2025, in the Korean Intellectual Property Office, the entire disclosure of which is incorporated herein by reference.

### BACKGROUND

Some example embodiments of the present disclosure relate to a display device and a method for fabricating the same.

A display device provides information to a user by displaying various images on a display screen. Generally, a display device includes a screen where images are displayed, and a bezel where no image is displayed.

As technology develops, a demand for display devices that display images are ever increasing. In terms of aesthetics, it is desirable for a display device to have a reduced bezel. Accordingly, a variety of design technologies for reducing the bezel of display devices are under development.

### SUMMARY

Some example embodiments of the present disclosure provide a display device that can save or reduce fabrication time and cost by reducing a bezel area and relatively simplify the fabrication process, and a method for fabricating the same.

Example embodiments are not limited to the above-mentioned embodiments; and other embodiments of the present disclosure will be apparent to those skilled in the art from the following descriptions.

According to some example embodiments of the present disclosure, a display device comprises a first substrate comprising a display area and a non-display area; a thin-film transistor layer on the first substrate, wherein the thin-film transistor layer comprises an insulating layer on the first substrate and overlapping with the display area and the non-display area, and a first back connection electrode on the insulating layer and overlapping with the non-display area; an emission material layer on the thin-film transistor layer and overlapping with the display area; a filling member on the insulating layer of the thin-film transistor layer and the first back connection electrode and on an outer side of the emission material layer; a second substrate on the emission material layer and the filling member; a touch connection pad on the second substrate and overlapping with the non-display area; and a touch connection line on the touch connection pad and the second substrate and extended along outermost sides of the second substrate, the filling member and the thin-film transistor layer on an outermost side of the first substrate and overlapping with the first back connection electrode, wherein the touch connection pad is electrically connected to the first back connection electrode through the touch connection line.

In some example embodiments, the outermost side of the filling member coincides with an outermost side of the first back connection electrode, and wherein the touch connection line is in direct contact with the outermost side of the first back connection electrode.

In some example embodiments, the first substrate comprises an opening penetrating the first substrate, wherein the thin-film transistor layer further comprises a back connection pad on the first substrate, overlapping with the non-display area and exposed through the opening, and wherein the back connection pad is electrically connected to the first back connection electrode through a fourth contact hole penetrating the insulating layer.

In some example embodiments, the display device further comprises a flexible printed circuit in the opening of the first substrate, wherein the flexible printed circuit board is electrically connected to the back connection pad, and wherein the touch connection pad is electrically connected to the flexible printed circuit board through the touch connection line, the first back connection electrode, and the back connection pad.

In some example embodiments, the touch connection line extends from the outermost side of the first substrate and on a lower surface of the first substrate and a lower surface of the back connection pad exposed through the opening, and wherein the touch connection line is in direct contact with the back connection pad.

In some example embodiments, the insulating layer of the thin-film transistor layer comprises a groove that is recessed inwardly from the outermost side of the first back connection electrode, wherein the touch connection line is on a lower surface of the first back connection electrode, an outermost side of the insulating layer and an upper surface of the first substrate defining the groove, and wherein the touch connection line is in direct contact with the lower surface of the first back connection electrode.

In some example embodiments, the outermost side of the filling member is located offset from the outermost side of the first back connection electrode, and wherein the touch connection line is in direct contact with an upper surface and the outermost side of the first back connection electrode, the upper surface and the outermost side of the first back connection electrode being offset from the filling member.

In some example embodiments, the thin-film transistor layer further comprises a thin-film transistor overlapping with the display area and on the insulating layer, and a first connection electrode on the insulating layer and electrically connected to the thin-film transistor through a first contact hole overlapping with the display area and penetrating the insulating layer, and wherein the first connection electrode and the first back connection electrode include a same material and the first connection electrode and the first back connection electrode are in a same layer.

In some example embodiments, the thin-film transistor layer further comprises a first via layer on the insulating layer and the first connection electrode, a second connection electrode on the first via layer and electrically connected to the first connection electrode through a second contact hole penetrating the first via layer, and a second back connection electrode between the first back connection electrode and the filling member and overlapping with the first back connection electrode, wherein the second connection electrode and the second back connection electrode include a same material and are in a same layer.

In some example embodiments, the outermost side of the filling member coincides with the outermost side of the first back connection electrode and an outermost side of the second back connection electrode, and wherein the touch connection line is in direct contact with the outermost side of the first back connection electrode and the outermost side of the second back connection electrode.

In some example embodiments, the thin-film transistor layer further comprises a first via layer on the insulating layer and the first connection electrode, a second connection electrode on the first via layer and electrically connected to the first connection electrode through a second contact hole penetrating the first via layer, a second via layer on the first via layer and the second connection electrode, and a third back connection electrode between the first back connection electrode and the filling member and overlapping with the first back connection electrode, wherein the emission material layer comprises an anode on the second via layer of the thin-film transistor layer and electrically connected to the second connection electrode through a third contact hole penetrating the second via layer, and wherein the anode and the third back connection electrode include a same material and are in a same layer.

In some example embodiments, the outermost side of the filling member coincides with the outermost side of the first back connection electrode and an outermost side of the third back connection electrode, and wherein the touch connection line is in direct contact with the outermost side of the first back connection electrode and the outermost side of the third back connection electrode.

According to some example embodiments of the present disclosure, a display device comprises a first substrate comprising a display area and a non-display area; a thin-film transistor layer on the first substrate, wherein the thin-film transistor layer comprises: an insulating layer on the first substrate and overlapping with the display area and the non-display area, and a back connection electrode on the insulating layer and overlapping with the non-display area; an emission material layer on the thin-film transistor layer and overlapping with the display area; a filling member on the insulating layer of the thin-film transistor layer and the back connection electrode and on an outer side of the emission material layer; a second substrate on the emission material layer and the filling member; a touch connection pad on the second substrate and overlapping with the non-display area; and a touch connection line on the touch connection pad and the second substrate, and on outermost sides of the second substrate, the filling member, and the thin-film transistor layer, the touch connection line overlapping with the back connection electrode, wherein the touch connection pad is electrically connected to the back connection electrode through the touch connection line.

In some example embodiments, the outermost side of the filling member coincides with an outermost side of the back connection electrode, and wherein the touch connection line is in direct contact with the outermost side of the back connection electrode.

In some example embodiments, the first substrate comprises an opening penetrating the first substrate, wherein the thin-film transistor layer further comprises a back connection pad on the first substrate, overlapping with the non-display area and exposed through the opening, and wherein the back connection pad is electrically connected to the back connection electrode through a fourth contact hole penetrating the insulating layer.

In some example embodiments, the display device further comprises a flexible printed circuit board in the opening of the first substrate, wherein the flexible printed circuit board is electrically connected to the back connection pad, and wherein the touch connection pad is electrically connected to the flexible printed circuit board through the touch connection line, the back connection electrode, and the back connection pad.

In some example embodiments, a portion of a lower surface of the insulating layer of the thin-film transistor layer is exposed by the opening, and wherein the touch connection line is on the lower surface of the insulating layer exposed by the opening and a lower surface of the back connection pad, and the touch connection line is in direct contact with the lower surface of the back connection pad.

In some example embodiments, the insulating layer of the thin-film transistor layer comprises a groove that is recessed inwardly from the outermost side of the back connection electrode, wherein the touch connection line is on the lower surface of the back connection electrode and an outermost side of the insulating layer defining the groove, and wherein the touch connection line is in direct contact with the lower surface of the back connection electrode.

In some example embodiments, the thin-film transistor layer further comprises a thin-film transistor overlapping with the display area and on the insulating layer, and a first connection electrode on the insulating layer and electrically connected to the thin-film transistor through a first contact hole overlapping with the display area and penetrating the insulating layer, and wherein the first connection electrode and the back connection electrode include a same material and are in a same layer.

According to some example embodiments of the present disclosure, an electronic device comprises a display device configured to display an image; and a processor configured to transmit an image data signal to the display device, the image data signal being configured to display the image, and wherein the display device comprises, a first substrate comprising a display area and a non-display area; a thin-film transistor layer on the first substrate, wherein the thin-film transistor layer comprises, an insulating layer on the first substrate and overlapping with the display area and the non-display area, and a first back connection electrode on the insulating layer and overlapping with the non-display area; an emission material layer on the thin-film transistor layer and overlapping with the display area; a filling member on the insulating layer of the thin-film transistor layer and the first back connection electrode and on an outer side of the emission material layer; a second substrate on the emission material layer and the filling member; a touch connection pad on the second substrate and overlapping with the non-display area; and a touch connection line on the touch connection pad and the second substrate and extending along outermost sides of the second substrate, the filling member, and the thin-film transistor layer and being on an outermost side of the first substrate and overlapping with the first back connection electrode, wherein the touch connection pad is electrically connected to the first back connection electrode through the touch connection line.

According to some example embodiments of the present disclosure, by connecting a touch connection pad with a line of a thin-film transistor layer through a touch connection line in a display device, the bezel area of the display device can be reduced and the fabrication process can be simplified, so that the fabrication time and cost can be saved.

It should be noted that example embodiments of the present disclosure are not limited to those described above and other embodiments of the present disclosure will be apparent to those skilled in the art from the following descriptions. Example embodiments are not limited to the above-mentioned embodiments; and other embodiments of the present disclosure will be apparent to those skilled in the art from the following descriptions

### BRIEF DESCRIPTION OF THE DRAWINGS

The above and other aspects and features of the present disclosure will become more apparent by describing in detail embodiments thereof with reference to the attached drawings, in which:

FIG. 1 is a view showing a rear side of a display device according to some example embodiments of the present disclosure.

FIG. 2 is an enlarged view of portion B1 of FIG. 1.

FIG. 3 is a cross-sectional view of a display device according to some example embodiments of the present disclosure, taken along line X1-X1′ of FIG. 2.

FIGS. 4, 5, 6, 7, 8, 9, 10, and 11 are cross-sectional views of display devices according to some example embodiments of the present disclosure, taken along line X1-X1′ of FIG. 2.

FIG. 12 is an enlarged view of portion B1 of FIG. 1 in a display device according to some example embodiments.

FIG. 13 is a cross-sectional view of a display device according to some example embodiments of the present disclosure, taken along line X3-X3′ of FIG. 12.

FIGS. 14, 15, 16, 17, 18, 19, 20, 21, and 22 illustrate processing steps for fabricating display devices according to some example embodiments of the present disclosure.

FIG. 23 is a block diagram of an electronic device according to some example embodiments of the present disclosure.

FIG. 24 illustrates electronic devices according to some example embodiments of the present disclosure.

### DETAILED DESCRIPTION OF THE EXAMPLE EMBODIMENTS

Example embodiments will now be described more fully hereinafter with reference to the accompanying drawings, in which some example embodiments of the present disclosure are shown. The example embodiments may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed as a second element without departing from the teachings of the disclosure. Similarly, the second element could also be termed as the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described in detail with reference to the accompanying drawings.

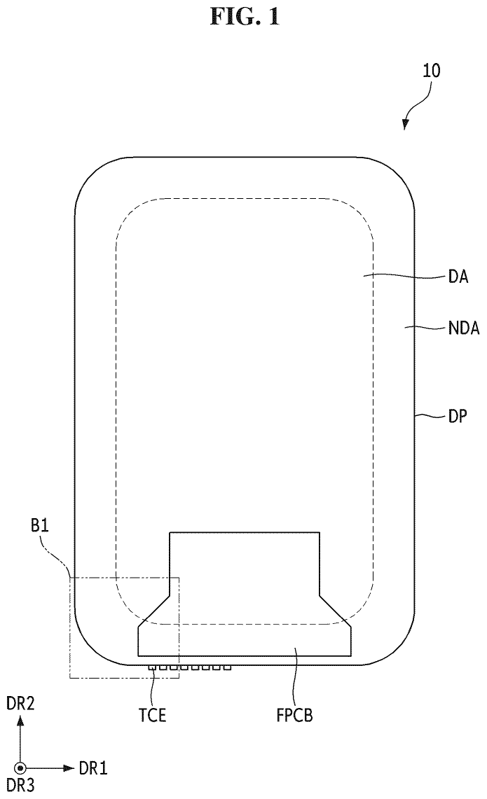

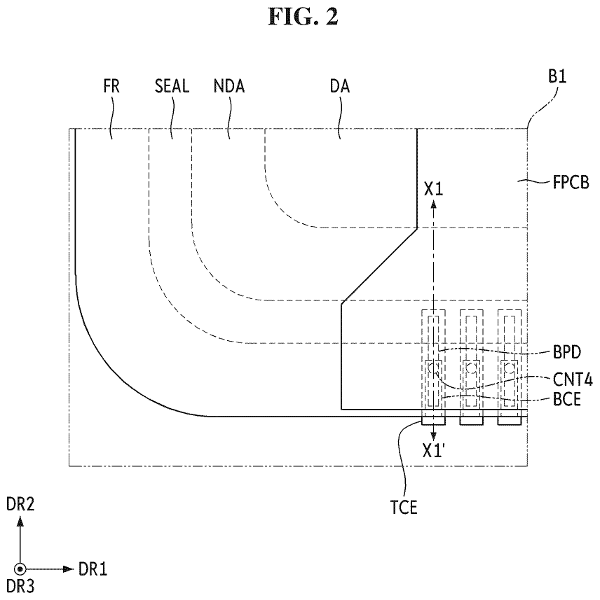

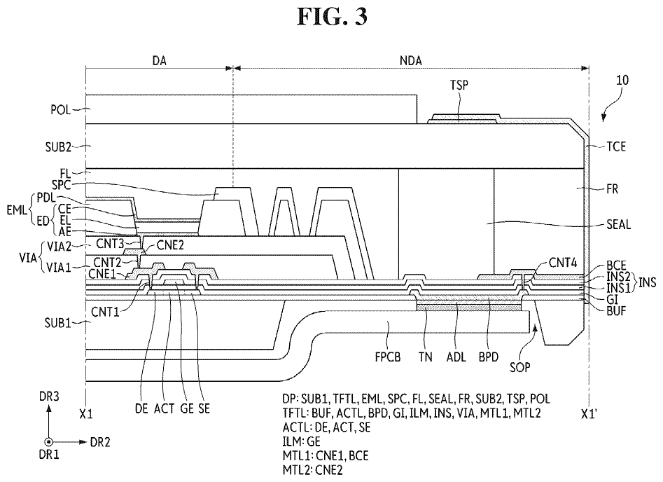

FIG. 1 is a view showing a rear side of a display device according to some example embodiments of the present disclosure. FIG. 2 is an enlarged view of portion B1 of FIG. 1. FIG. 3 is a cross-sectional view of a display device according to some example embodiments of the present disclosure, taken along line X1-X1′ of FIG. 2.

Referring to FIG. 1, the display device 10 displays a moving image or a still image. The display device 10 may refer to any display device that provides a display screen.

The display device 10 may be a light-emitting display device such as an organic light-emitting display device using organic light-emitting diodes, a quantum-dot light-emitting display device including a quantum-dot emissive layer, an inorganic light-emitting display device including an inorganic semiconductor, and a micro light-emitting display device using micro or nano light-emitting diodes (micro LEDs or nano LEDs). In the following description, an organic light-emitting display device is described as an example of the display device 10. It is, however, to be understood that example embodiments are not limited thereto.

The shape of the display device 10 may be modified in a variety of ways. For example, the display device 10 may have shapes such as a rectangle with longer lateral sides, a rectangle with longer vertical sides, a square, a quadrangle with rounded corners (vertices), other polygons, a circle, etc. In the example shown in FIG. 1, the display device 10 has a rectangular shape with the longer sides in a second direction DR2 and rounded corners.

As used herein, a first direction DR1 may be parallel to the shorter sides of the display device 10, for example, the horizontal direction of the display device 10 when viewed from the top. A second direction DR2 may be parallel to the longer sides of the display device 10, for example, the vertical direction of the display device 10 when viewed from the top. A third direction DR3 may refer to the thickness direction of the display device 10.

The display device 10 may include the display area DA and a non-display area NDA. In the display area DPA, images can be displayed. In the non-display area NDA, images are not displayed. The display area DA may be located in the center (or in a generally central location) of the display device 10, and the non-display area NDA may be located outside (or along the periphery of) the display area DA and surround the display area DA.

Subsequently, referring to FIGS. 1 to 3, the display device 10 may include a display panel DP, a flexible circuit board FPCB, and a touch connection line TCE.

The display panel DP may include a first substrate SUB1, a thin-film transistor layer TFTL, an emission material layer EML, a spacer SPC, a sealing member SEAL, a filling layer FL, a filling member FR, a second substrate SUB2, a polarizing member POL, and a touch connection pad TSP.

The first substrate SUB1 may be a base member that supports layers of the display panel DP. The first substrate SUB1 may be located across the display area DA and the non-display area NDA. According to some example embodiments, the first substrate SUB1 may be a relatively rigid substrate and may include a glass material or a metal material. Alternatively, in some example embodiments, the first substrate SUB1 may be a flexible substrate that can be bent, folded, rolled and so on, and may include a polymer resin such as polyimide (PI).

The first substrate SUB1 may include an opening SOP. The opening SOP of the first substrate SUB1 may be etched so that it penetrates from the lower surface of the first substrate SUB1 to the upper surface of the first substrate SUB1. For example, the width of the bottom of the opening SOP of the first substrate SUB1 may be greater than the width of the top of the opening SOP of the first substrate SUB1. A flexible printed circuit board FPCB may be inserted into the opening SOP of the first substrate.

The thin-film transistor layer TFTL may be located on the first substrate SUB1. The thin-film transistor layer TFTL may be located in the display area DA and the non-display area NDA. The thin-film transistor layer TFTL may include a buffer layer BUF, a back connection pad BPD, an active layer ACTL, a gate insulator GI, an interlayer metal layer ILM, an interlayer dielectric layer INS, a first metal layer MTL1, a first via layer VIA1, a second metal layer MTL2, and a second via layer VIA2.

The buffer layer BUF may be located on the first substrate SUB1. The buffer layer BUF may be located in the display area DA and the non-display area NDA. The buffer layer BUF may include an inorganic material that can prevent (or limit or reduce) the permeation of air or moisture. The buffer layer BUF may include multiple inorganic films stacked on one another.

The buffer layer BUF may include a through hole penetrating the buffer layer BUF in the non-display area NDA, in which the back connection pad BPD is provided, which will be described later.

A part of the buffer layer BUF may be exposed by the opening SOP of the first substrate together with the back connection pad BPD provided in the through hole of the buffer layer BUF, which will be described later.

The back connection pad BPD may be located on the first substrate SUB1 and the buffer layer BUF. For example, the back connection pad BPD may be located on the first substrate SUB1 in the through hole of the buffer layer BUF, and a part of the back connection pad BPD may be further located on (e.g., on an upper surface of) the buffer layer BUF. The back connection pad BPD may be located in the non-display area NDA. The back connection pad BPD may be electrically connected to lines for forming a circuit for driving a transistor included in a thin-film transistor layer TFTL. The back connection pad BPD may be made up of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu).

The back connection pad BPD may be exposed by the opening SOP of the first substrate SUB1. The back connection pad BPD may be electrically connected to the flexible printed circuit board FPCB inserted into the opening SOP of the first substrate SUB1.

The active layer ACTL may be located on (e.g., on an upper surface of) the buffer layer BUF. The active layer ACTL may be located in the display area DA and may be located further in the non-display area NDA. The active layer ACTL may include a semiconductor region ACT, a drain region DE, and a source region SE of a transistor.

The gate insulator GI may be located on (e.g., on upper surfaces of) the buffer layer BUF, the back connection pad BPD, and the active layer ACTL. The gate insulator GI may be located in the display area DA and the non-display area NDA. The gate insulator GI may include an inorganic film that can insulate the active layer ACTL from the gate electrode GE. The gate insulator GI may include or define a first contact hole CNT1 through which the first connection electrode CNE1 passes, and a fourth contact hole CNT4 through which the back connection electrode BCE passes.

The interlayer metal layer ILM may be located on (e.g., on an upper surface of) the gate insulator GI. The interlayer metal layer ILM may be located in the display area DA and may be further located in the non-display area NDA. The interlayer metal layer ILM may include the gate electrode GE of the transistor, a capacitor electrode, etc. The gate electrode GE may overlap with the semiconductor region ACT with the gate insulator GI interposed between the gate electrode GE and the semiconductor region ACT. The gate electrode GE may receive scan signals from the scan lines. The interlayer metal layer ILM may be made up of a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu).

The interlayer dielectric layer INS may be located on the interlayer metal layer ILM and the gate insulator GI. The interlayer dielectric layer INS may be located in the display area DA and the non-display area NDA. The interlayer dielectric layer INS may insulate the interlayer metal layer ILM from the first metal layer MTL1. The interlayer dielectric layer INS may include a plurality of inorganic films that are alternately stacked on one another. For example, the interlayer dielectric layer INS may include a first interlayer dielectric layer INS1 located on (e.g., on upper surfaces of) the interlayer metal layer ILM and the gate insulator GI, and a second interlayer dielectric layer INS2 located on (e.g., on an upper surface of) the first interlayer dielectric layer INS1.

The interlayer dielectric layer INS may include or define a first contact hole CNT1 and a fourth contact hole CNT4 through which the first connection electrode CNE1 and the back connection electrode BCE pass, respectively.

The first metal layer MTL1 may be located on the interlayer dielectric layer INS, for example, on an upper surface of the second interlayer dielectric layer INS2. The first metal layer MTL1 may be located in the display area DA and the non-display area NDA. The first metal layer MTL1 may include the first connection electrode CNE1 and the back connection electrode BCE. The first connection electrode CNE1 and the back connection electrode BCE may be made of or include the same material and may be in the same layer (or level). For example, the first metal layer MTL1 may be made up of or include a single layer or multiple layers including at least one of: molybdenum (Mo), aluminum (Al), chromium (Cr), gold (Au), silver (Ag), titanium (Ti), nickel (Ni), palladium (Pd), indium (In), neodymium (Nd), and copper (Cu).

The first connection electrode CNE1 may be located in the display area DA and may be further located in the non-display area NDA. The first connection electrode CNE1 may electrically connect the drain region DE of the transistor with a second connection electrode CNE2. The first connection electrode CNE1 may be inserted into the first contact hole CNT1 penetrating the interlayer dielectric layer INS and the gate insulator GI and may be connected to a drain electrode DE and/or a source electrode SE of the transistor. The first connection electrode CNE1 may provide a driving current received from a pixel circuit to the second connection electrode CNE2.

The back connection electrode BCE may be located in the non-display area NDA. The back connection electrode BCE may be located at the outermost edge in the non-display area NDA. The back connection electrode BCE can be inserted into the fourth contact hole CNT4 penetrating the interlayer dielectric layer INS and the gate insulator GI and may be connected to the back connection pad BPD. In addition, the back connection electrode BCE may be connected to the touch connection line TCE.

The first via layer VIA1 may be located on (e.g., on upper surfaces of) the first metal layer MTL1 and the interlayer dielectric layer INS. For example, the first via layer VIA1 may be located on upper surfaces of the first connection electrode CNE1 and the back connection electrode BCE and the upper surfaces of the second interlayer dielectric layer INS2. The first via layer VIA1 may be located in the display area DA and further located in the non-display area NDA. The first via layer VIA1 may protect the transistor and provide a relatively flat surface over the thin-film transistor layer TFTL. The first via layer VIA1 may be or include an organic insulating material such as polyimide (PI). The first via layer VIA1 may be or include a second contact hole CNT2 through which the second connection electrode CNE2 passes.

The second metal layer MTL2 may be located on (e.g., on an upper surface of) the first via layer VIA1. The second metal layer MTL2 may include the second connection electrode CNE2. The second connection electrode CNE2 may electrically connect the first connection electrode CNE1 with an anode AE of a light-emitting element ED. The second connection electrode CNE2 may supply a driving current received from the first connection electrode CNE1 to the light-emitting element ED.

The second via layer VIA2 may be located on (e.g., on upper surfaces of) the first via layer VIA1 and the interlayer dielectric layer INS. The second via layer VIA2 may include a third contact hole CNT3 through which the anode AE of the light-emitting element ED passes.

An emission material layer EML may be located on (e.g., on an upper surface of) the thin-film transistor layer TFTL. The emission material layer EML may include a light-emitting element ED and a pixel-defining layer PDL.

The light-emitting element ED may be located on (e.g., on an upper surface of) the second via layer VIA2 and may be located in the display area DA. The light-emitting element ED may include an anode AE, an emissive layer EL, and a cathode CE. The anode AE may be located on (e.g., on an upper surface of) the second via layer VIA2. The anode AE may overlap with an emission area defined by the pixel-defining layer PDL. For example, the anode AE may receive a driving current from a pixel circuit through the connection electrodes CNE1 and CNE2.

The emissive layers EL may be located on (e.g., on an upper surface of) the anode AE. For example, the emissive layer EL may be, but is not limited to, an organic emissive layer made of an organic material. If the emissive layer EL is an organic emissive layer, when the pixel circuit of the pixel applies a predetermined voltage to the anode AE and the cathode CE receives a cathode voltage, holes may move to the emissive layer EL through a hole transporting layer and electrons may move to the emissive layer EL through a hole transporting layer, and they combine in the emissive layer EL to emit light.

The cathode CE may be arranged on the emissive layer EL. For example, the cathode CE may be implemented as an electrode common to all pixels, instead of being disposed as a separated electrode for each of the pixels. The cathode CE may be located on the emissive layer EL in the emission areas and may be located on the pixel-defining layer PDL in the other areas than the emission area.

The pixel-defining layer PDL may be located on the second via layer VIA2 and the interlayer dielectric layer INS. The pixel-defining layer PDL may be located in the display area DA and may be further located in the non-display area NDA. The pixel-defining layer PDL may define a plurality of emission areas or a plurality of openings. The pixel-defining layer PDL may separate and insulate the anodes AE of the pixels from one another.

The spacer SPC may be located on (e.g., on upper surfaces of) the pixel-defining layer PDL of the emission material layer EML, the second via layer VIA2 of the thin-film transistor layer TFTL, and the interlayer dielectric layer INS. The spacer SPC may control the gap between the second substrate SUB2 and the emission material layer EML.

The sealing member SEAL may be located on (e.g., on upper surfaces of) the interlayer dielectric layer INS and the back connection electrode BCE of the thin-film transistor layer TFTL. The sealing member SEAL may be located in the non-display area NDA and may be located more to the outside (e.g., relatively closer to the outer edge of the display device 10) than the first via layer VIA1 and the second via layer VIA2 and the emission material layer EML of the thin-film transistor layer TFTL. The sealing member SEAL may surround the outer side of the emission material layer EML to protect the side surface of the emission material layer EML. The sealing member SEAL may be or include an inorganic material to prevent (or limit or reduce) oxygen or moisture from permeating into the emission material layer EML.

The filling layer FL may be located on (e.g., on upper surfaces of) the emission material layer EML and the thin-film transistor layer TFTL. In some example embodiments, the filling layer FL may be or include an organic material that may fill the space defined by the emission material layer EML, the transistor layer TFTL and the second substrate SUB2. Alternatively, in some example embodiments, the filling layer FL may be an empty space (void, gap, or opening) defined by the emission material layer EML, the transistor layer TFTL and the second substrate SUB2.

The filling member FR may be located on (e.g., on upper surfaces of) the interlayer dielectric layer INS and the back connection electrode BCE. The filling member FR may be located in the non-display area NDA and may be located outside (e.g., towards the outer periphery of) the sealing member SEAL. In some example embodiments, the outermost side of the filling member FR may be aligned with (or flush with) the outermost side of the first substrate SUB1, the outermost side of the thin-film transistor layer TFTL, and the outermost side of the second substrate SUB2. Alternatively, in some example embodiments, the outermost side of the filling member FR may be offset from, e.g., located more to the inside (e.g., in the direction of the display area DA) than the outermost side of the first substrate SUB1, the outermost side of the thin-film transistor layer TFTL, and the outermost side of the second substrate SUB2. The filling member FR may be or include an acrylic material, a silicone material, a resin, etc.

The second substrate SUB2 may be located over (e.g., on upper surfaces of) the emission material layer EML, the sealing member SEAL, and the filling member FR. The second substrate SUB2 may be located in the display area DA as well as the non-display area NDA. The second substrate SUB2 may include at least one inorganic layer and may function as an encapsulation layer that prevents (or limits or reduces) oxygen or moisture from permeating into the plurality of light-emitting elements ED. The second substrate SUB2 may be or include at least one organic film to protect the light-emitting elements ED from particles such as dust.

The display panel DP may further include a touch sensing unit. The touch sensing unit may be located on the second substrate SUB2. The touch sensing unit may include a plurality of touch electrodes for sensing a user's touch by capacitive sensing, and touch lines providing the plurality of touch electrodes with touch driving signals. For example, the touch sensing unit may sense a user's touch by mutual-capacitance sensing or self-capacitance sensing. The touch electrodes of the touch sensing unit may be arranged in the touch sensing area overlapping with the display area DA. The touch lines of the touch sensing unit are arranged in a touch peripheral area overlapping with the non-display area NDA and may be electrically connected to the touch connection pad TSP.

The touch connection pad TSP may be located on the second substrate SUB2. The touch connection pad TSP may be located in the non-display area NDA. There may be a plurality of touch connection pads TSP, which may be spaced apart from one another in the first direction DR1. The touch connection pad TSP may be electrically connected to the touch sensing unit and the touch connection line TCE.

The polarizing member POL may be located on (e.g., on an upper surface of) the second substrate SUB2. The polarizing member POL may be located in the display area DA and may be further located in the non-display area NDA. The polarizing member POL may be attached on or may contact the touch sensing unit using an optically clear adhesive (OCA) film or an optically clear resin (OCR). For example, the polarizing member POL may include a linear polarizer and a retarder film. The retarder film may be a λ/4 plate (quarter-wave plate). The retarder film and the linear polarizer may be sequentially stacked on the touch sensing unit. The polarizing member POL can reduce reflection of external light to prevent or reduce color distortion due to the reflection of the external light.

The touch connection line TCE may be located on the upper surface and a side surface of the display panel DP. For example, the touch connection line TCE may be located on the touch connection pad TSP of the display panel DP and the second substrate SUB2, may be extended along the outermost side of the second substrate SUB2 of the display panel DP, the outermost side of the filling member FR and the outermost side of the thin-film transistor layer TFTL such that the touch connection line TCE is further located at least partially on the side surface of the first substrate SUB1, and may overlap with the back connection electrode BCE of the thin-film transistor layer TFTL. In some example embodiments, the display device 10 may include a plurality of touch connection lines TCE that may be spaced apart from one another in the first direction DR1. The plurality of touch connection lines TCE may be electrically connected with the plurality of touch connection pads TSP, respectively. The touch connection lines TCE may be or include a metal material including aluminum (Al), copper (Cu), silver (Ag), etc. The touch connection lines TCE may electrically connect the touch connection pad TSP of the display panel DP with the back connection electrode BCE. In some example embodiments where the outermost side of the filling member FR is aligned with the side surface of the back connection electrode BCE, the touch connection line TCE may be in direct contact with the outermost side of the back connection electrode BCE. Alternatively, in some example embodiments where the outermost side of the filling member FR is located more to the inside than the outermost side of the back connection electrode BCE, the touch connection line TCE may be in direct contact with the outermost side of the back connection electrode BCE and may be in direct contact with the upper surface of the back connection electrode BCE that is located more to the outside than the filling member FR. As the touch connection pad TSP is connected to the back connection electrode BCE of the thin-film transistor layer TFTL by the touch connection line TCE, a separate (e.g., discrete) flexible printed circuit board that may be directly connected to the touch connection pad may be omitted in the display device 10, and therefore, the bezel area of the display device 10 may be reduced.

A flexible printed circuit board FPCB may be located under the display panel DP. The flexible printed circuit board FPCB may be placed under the first substrate SUB1 of the display panel DP. One side of the flexible printed circuit board FPCB may be inserted into the opening SOP of the first substrate SUB1 and electrically connected to the back connection pad BPD, and may be attached to the lower surface of the back connection pad BPD exposed by the opening SOP of the first substrate using an adhesive member ADL. The adhesive member ADL may be or include an anisotropic conductive film (ACF). The flexible printed circuit board FPCB may include a terminal TN located on one side of the upper surface and inserted into the opening SOP. The terminal TN may protrude from one side of the flexible printed circuit board FPCB and may overlap with the back connection pad BPD. The upper surface of the terminal TN may be in direct contact with the back connection pad BPD, and the upper surface of the terminal TN may be electrically connected to the back connection pad BPD through the adhesive member ADL. A plurality of touch signal lines electrically connected to the terminal TN, and a touch driving integrated circuit for driving the touch sensing unit may be arranged on the other side of the upper surface or the lower surface of the flexible printed circuit board FPCB. In addition, on the other side of the upper surface or the lower surface of the flexible printed circuit board FPCB, a plurality of display signal lines electrically connected to the terminal TN, a transistor and a capacitor in the thin-film transistor layer TFTL, a display driving integrated circuit for driving the light-emitting element ED of the emission material layer EML, etc. may be arranged. The flexible printed circuit board FPCB may transmit signals and voltages from the display driver integrated circuit and the touch driver integrated circuit to the display device 10 through the back connection pad BPD.

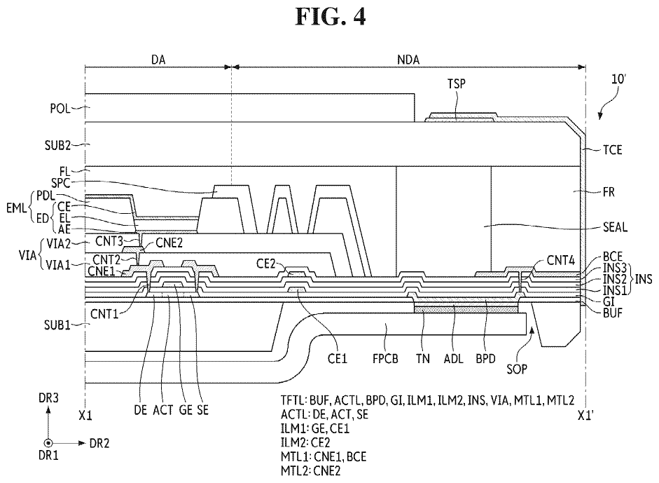

FIGS. 4, 5, 6, 7, 8, 9, 10, and 11 are cross-sectional views of display devices according to a variety of embodiments of the present disclosure, taken along line X1-X1′ of FIG. 2.

The display devices in FIGS. 4, 5, 6, 7, 8, 9, 10, and 11 may be same as or similar in some respects to the display devices in FIGS. 2 and 3, and therefore may be best understood with reference thereto where like numerals indicate like elements not described again in detail.

Referring to FIG. 4, with reference to FIG. 3, a thin-film transistor layer TFTL may include a buffer layer BUF, a back connection pad BPD, an active layer ACTL, a gate insulator GI, a first interlayer metal layer ILM1, an interlayer dielectric layer INS, a second interlayer metal layer ILM2, a first metal layer MTL1, a first via layer VIA1, a second metal layer MTL2, a second via layer VIA2.

The first interlayer metal layer ILM1 may be located on the gate insulator GI and may include a gate electrode GE and a first capacitor electrode CE1.

The interlayer dielectric layer INS may include a first interlayer dielectric layer INS1, a second interlayer dielectric layer INS2, and a third interlayer dielectric layer INS3 that are sequentially stacked on one another.

The second interlayer metal layer ILM2 may be located on the second interlayer dielectric layer INS2 and may include a second capacitor electrode CE2. The second capacitor electrode CE2 may overlap with the first capacitor electrode CE1. A capacitor including the first capacitor electrode CE1 and the second capacitor electrode CE2 may be a storage capacitor for driving a circuit of a thin-film transistor.

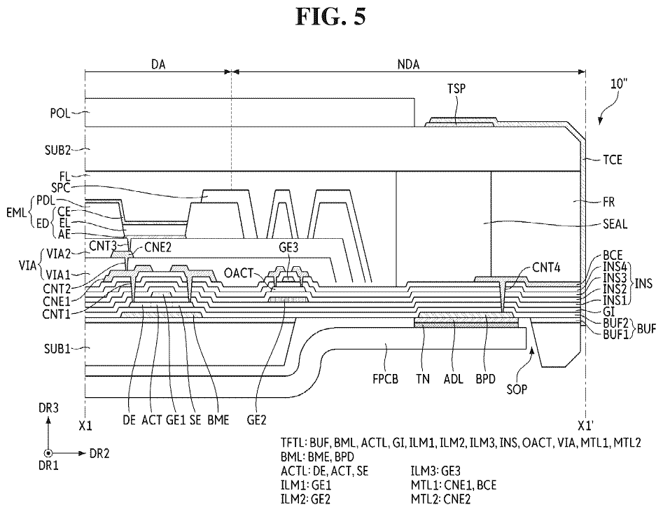

Referring to FIG. 5, with reference to FIG. 3, a thin-film transistor layer TFTL may include a buffer layer BUF, a bottom metal layer BML, a first active layer ACTL, a gate insulator GI, a first interlayer metal layer ILM1, an interlayer dielectric layer INS, a second interlayer metal layer ILM2, a second active layer OACT, a third interlayer metal layer ILM3, a first metal layer MTL1, a first via layer VIA1, a second metal layer MTL2, and a second via layer VIA2.

The buffer layer BUF may include a first buffer layer BUF1 and a second buffer layer BUF2 that are sequentially stacked on one another. The first buffer layer BUF1 may include an opening that may correspond to or may be aligned with an opening SOP of a first substrate. The opening of the first buffer layer BUF1 may be etched together with the opening SOP of the first substrate SUB1 and may penetrate from a lower surface of the first buffer layer BUF1 to an upper surface of the first buffer layer BUF1. The opening of the first buffer layer BUF1 may overlap with the opening SOP of the first substrate. The second buffer layer BUF2 may include or define a fourth contact hole CNT4 through which the back connection electrode BCE passes.

The bottom metal layer BML may be located between the first buffer layer BUF1 and the second buffer layer BUF2. The bottom metal layer BML may include a bottom metal electrode BME and a back connection pad BPD. The bottom metal electrode BME may overlap with the first active layer ACTL with the second buffer layer BUF2 between the bottom metal layer BME and the first active layer ACTL. The back connection pad BPD may be exposed by the opening of the first buffer layer BUF1 and the opening SOP of the first substrate.

The interlayer dielectric layer INS may include a first interlayer dielectric layer INS1, a second interlayer dielectric layer INS2, a third interlayer dielectric layer INS3, and a fourth interlayer dielectric layer INS4 that are sequentially stacked on one another.

The second interlayer metal layer ILM2 may be located on the first interlayer dielectric layer INS1 and may include a second gate electrode GE2.

The second active layer OACT may be located on the second interlayer dielectric layer INS2. The second active layer OACT may be located in the non-display area NDA. The second active layer OACT may include a semiconductor region, a drain region, and a source region of a transistor. The second active layer OACT may include a metal oxide such as IGZO. The second active layer OACT may overlap with the second gate electrode GE2 with the second interlayer dielectric layer INS2 between the second active layer OACT and the second gate electrode GE2.

The third interlayer metal layer ILM3 may be located on the third interlayer dielectric layer INS3 and may include a third gate electrode GE3. The third gate electrode GE3 may overlap with the semiconductor region of the second active layer OACT with the third interlayer dielectric layer INS3 between the third gate electrode GE3 and the semiconductor region.

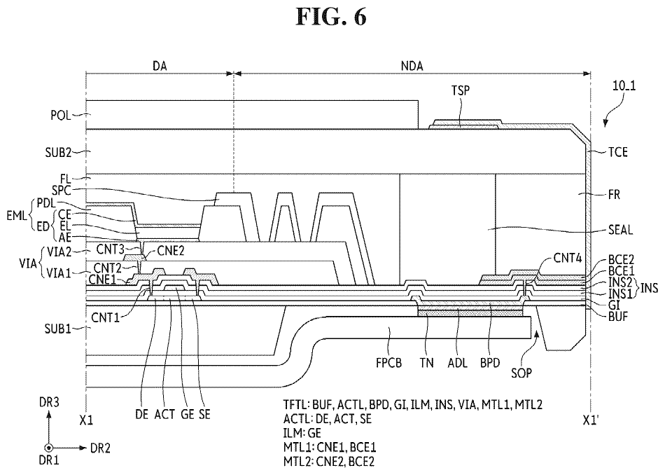

Referring to FIG. 6, with reference to FIG. 3, the back connection electrode BCE may include a first back connection electrode BCE1 and a second back connection electrode BCE2. The first back connection electrode BCE1 may be located on the interlayer dielectric layer INS and may be located in the non-display area NDA. The second back connection electrode BCE2 may be located on the first back connection electrode BCE1 and may overlap with the first back connection electrode BCE1. In some example embodiments, the second back connection electrode BCE2 may be an electrode made of or including the same material and may be in the same layer (or level) as the second connection electrode CNE2 located on the first via layer VIA1. Alternatively, in some example embodiments, the second back connection electrode BCE2 may be an electrode made of or including the same material and may be in the same layer as the anode AE located on the second via layer VIA2. The outermost side of the filling member FR may be aligned with the outermost side of the first back connection electrode BCE1 and the second back connection electrode BCE2, and the touch connection line TCE may be in direct contact with the outermost side of the first back connection electrode BCE1 and the second back connection electrode BCE2. As the touch connection line TCE may be in direct contact with the outermost side of the first back connection electrode BCE1 and the outermost side of the second back connection electrode BCE2, the contact area between the back connection electrode BCE and the touch connection wire TCE becomes larger, so that the contact resistance can be reduced. In addition, by connecting the touch connection pad TSP with the back connection electrode BCE of the thin-film transistor layer TFTL through the touch connection line TCE, the bezel area of the display device can be reduced.

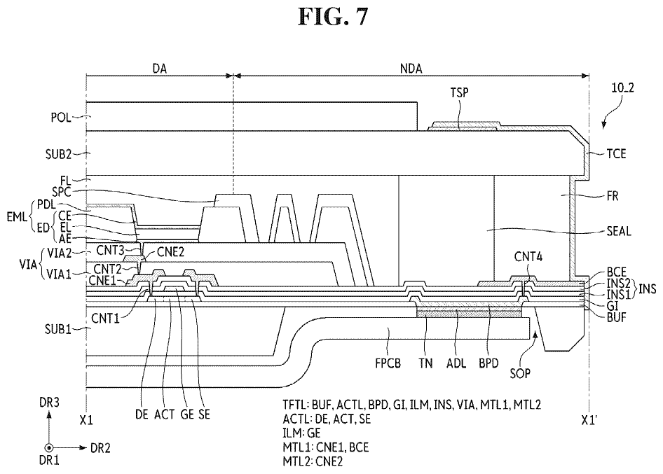

Referring to FIG. 7, with reference to FIG. 3, the outermost side of the filling member FR may be offset from the outermost sides of the second substrate SUB2, the thin-film transistor layer TFTL and the first substrate SUB1. For example, the outermost side of the filling member FR may be located more to the inside than the outermost sides of the second substrate SUB2, the thin-film transistor layer TFTL and the first substrate SUB1. As the outermost side of the filling member FR is located more to the inside than the outermost side of the back connection electrode BCE included in the thin-film transistor layer TFTL, the touch connection line TCE may be in direct contact with the upper surface and the outermost side of the back connection electrode BCE located more to the outside than the filling member FR. As a result, the contact area between the touch connection line TCE and the back connection electrode BCE becomes larger, so that the contact resistance can be reduced. In addition, by connecting the touch connection pad TSP with the back connection electrode BCE of the thin-film transistor layer TFTL through the touch connection line TCE, the bezel area of the display device can be reduced.

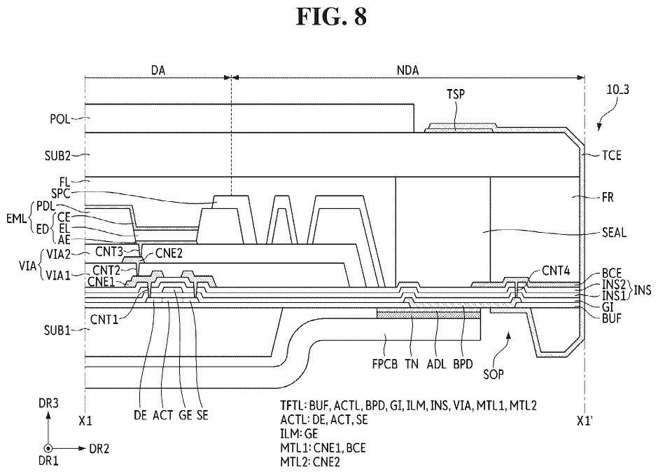

Referring to FIG. 8, with reference to FIG. 3, the touch connection line TCE may be further extended from the outermost side of the first substrate, may be located further on the lower surface of the first substrate SUB1 and the lower surface of the back connection pad BPD exposed through the opening SOP of the first substrate, and may be in direct contact with the lower surface of the back connection pad BPD. As illustrated, a width of the opening SOP in the second direction DR2 may be more than the width of the opening SOP in FIG. 3. As the touch connection line TCE is in direct contact with the outermost side of the back connection electrode BCE and the lower surface of the back connection pad BPD, the electrical connection between the touch connection pad TSP and the back connection pad BPD can be further improved In addition, by connecting the touch connection pad TSP with the back connection electrode BCE of the thin-film transistor layer TFTL and the back connection electrode BCE through the touch connection line TCE, the bezel area of the display device can be reduced.

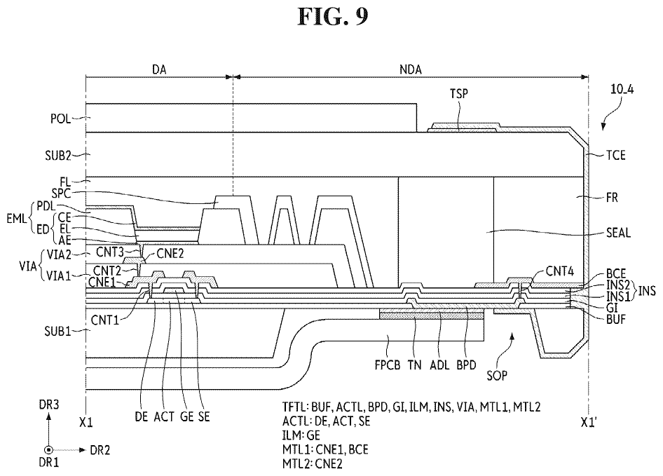

Referring to FIG. 9, with reference to FIG. 8, the buffer layer BUF, the gate insulator GI and the interlayer dielectric layer INS of the thin-film transistor layer TFTL may include a groove that is recessed inwardly from the outermost side of the back connection electrode BCE. As a result, the touch connection line TCE may be located further on the lower surface of the back connection electrode BCE, the outermost sides of the buffer layer BUF, the gate insulator GI and the interlayer dielectric layer INS defining the groove, and the upper surface of the first substrate SUB1. The touch connection line TCE may be further in direct contact with the lower surface of the back connection electrode BCE. As a result, the contact area between the touch connection line TCE and the back connection electrode BCE is increased, so that the contact resistance can be reduced and the electrical connection between the touch connection pad TSP and the back connection pad BPD can be further improved. In addition, by connecting the touch connection pad TSP with the back connection electrode BCE of the thin-film transistor layer TFTL and the back connection electrode BCE through the touch connection line TCE, the bezel area of the display device can be reduced.

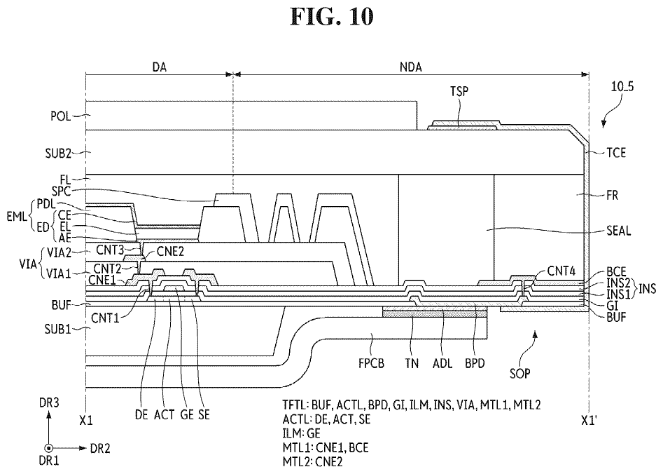

Referring to FIG. 10, with reference to FIG. 3, an opening SOP of a first substrate may be expanded so that it overlaps with a filling member FR. A part of the lower surface of the buffer layer BUF of the thin-film transistor layer TFTL may be exposed by an opening SOP of the first substrate, and the touch connection line TCE may be further located on the lower surface of the buffer layer BUF and the lower surface of the back connection pad BPD exposed by the opening SOP and may be in direct contact with the lower surface of the back connection pad BPD. As the touch connection line TCE is in direct contact with the outermost side of the back connection electrode BCE and the lower surface of the back connection pad BPD, the electrical connection between the touch connection pad TSP and the back connection pad BPD can be further improved In addition, by connecting the touch connection pad TSP with the back connection electrode BCE of the thin-film transistor layer TFTL and the back connection electrode BCE through the touch connection line TCE, the bezel area of the display device can be reduced.

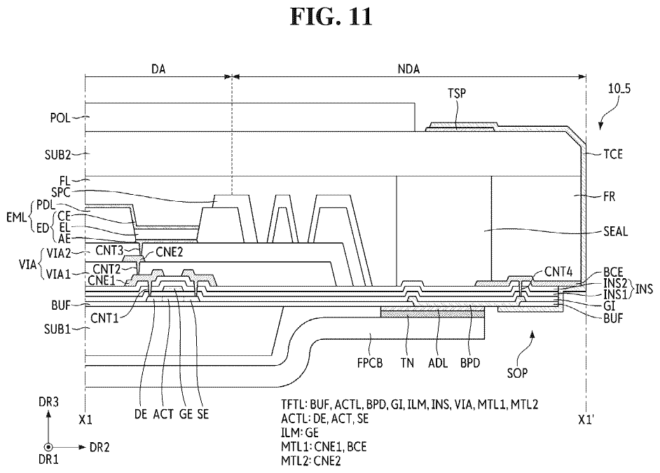

Referring to FIG. 11, with reference to FIG. 10, the buffer layer BUF, the gate insulator GI and the interlayer dielectric layer INS of the thin-film transistor layer TFTL may include a groove that is recessed inwardly from the outermost side of the back connection electrode BCE. The touch connection line TCE may be located further on the lower surface of the back connection electrode BCE, and the outermost sides of the buffer layer BUF, the gate insulator GI and the interlayer dielectric layer INS defining the groove The touch connection line TCE may be further in direct contact with the lower surface of the back connection electrode BCE. As a result, the contact area between the touch connection line TCE and the back connection electrode BCE can be increased, so that the contact resistance can be reduced.

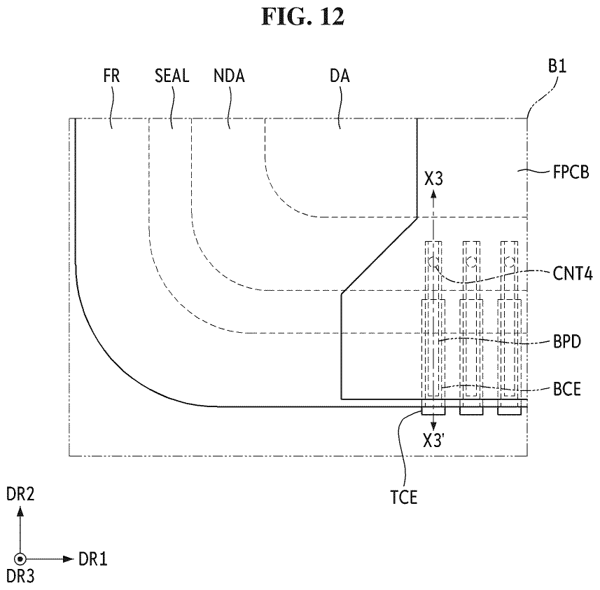

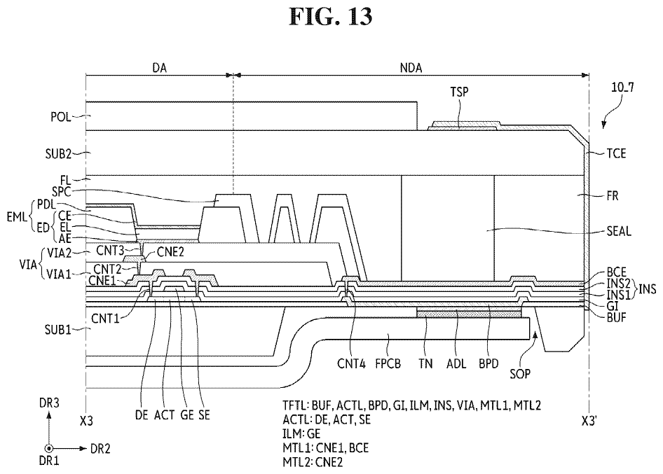

FIG. 12 is an enlarged view of portion B1 of FIG. 1 in a display device according to some example embodiments. FIG. 13 is a cross-sectional view of a display device according to some example embodiments of the present disclosure, taken along line X3-X3′ of FIG. 12.

Referring to FIGS. 12 and 13, with reference to FIGS. 2 and 3, the back connection electrode TCE and/or the back connection pad BPD may be extended toward the inside of the display panel, and a fourth contact hole CNT4 penetrating an interlayer dielectric layer INS and a gate insulator GI may be located more to the inside than a sealing member SEAL. As the fourth contact hole CNT4 connecting the back connection electrode BCE and the back connection pad BPD is located more to the inside than the sealing member SEAL, the non-display area NDA overlapping with the sealing member SEAL and the filling member FR can be reduced. As a result, the bezel area can be further reduced.

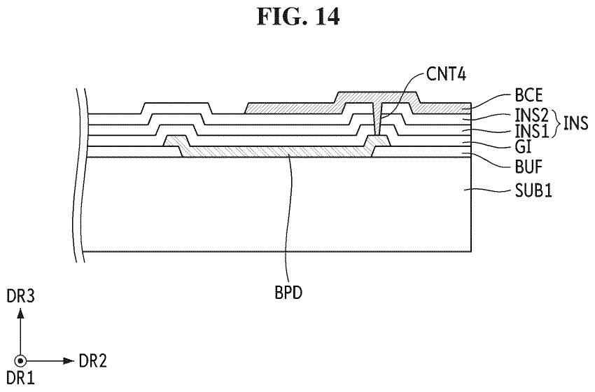

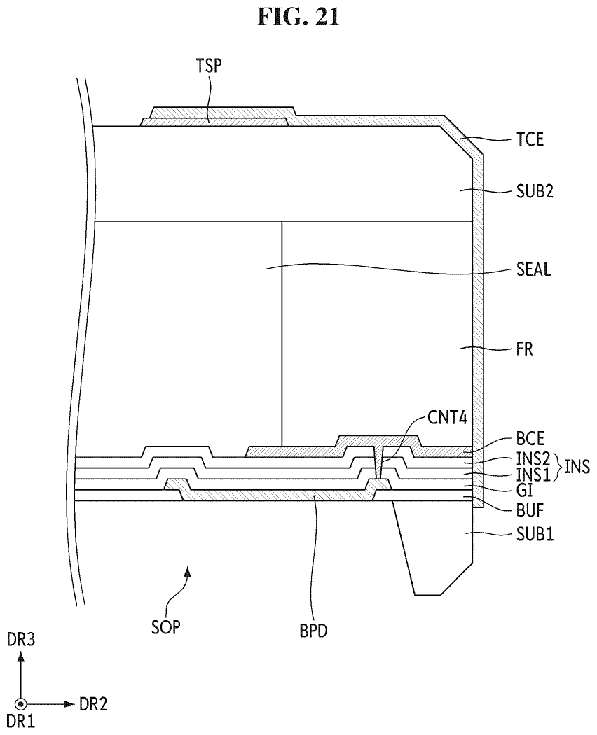

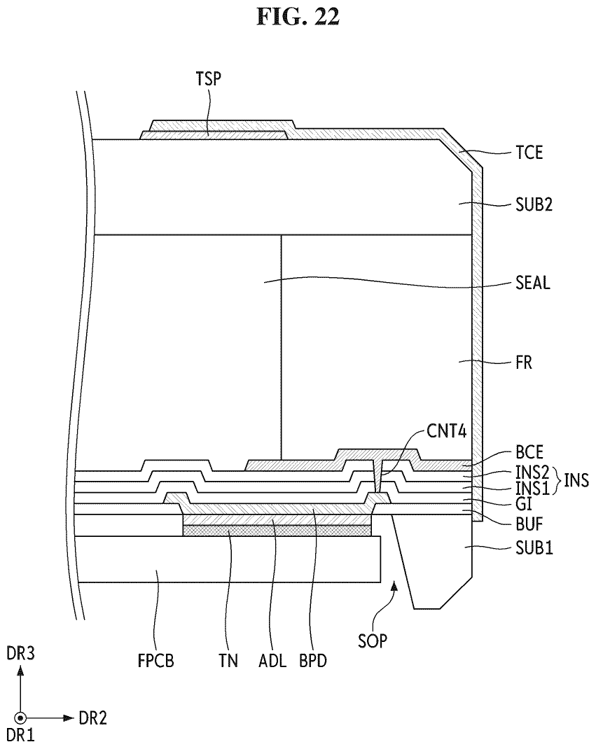

FIGS. 14, 15, 16, 17, 18, 19, 20, 21, and 22 illustrate operations in a method of fabricating display devices according to some example embodiments of the present disclosure. It is understood that additional operations can be provided before, during, and after the operations in FIGS. 14, 15, 16, 17, 18, 19, 20, 21, and 22, and some of the operations described below can be replaced or eliminated, for additional embodiments of the method. The order of the operations/processes may be interchangeable, or two or more operations can be performed simultaneously.

FIGS. 14 to 16 illustrate operations of preparing a display panel for fabricating a display device.

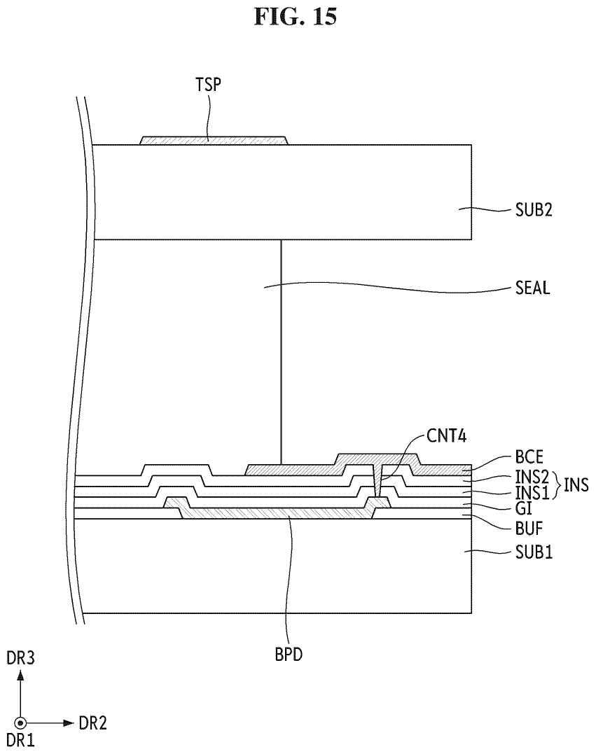

Initially, referring to FIGS. 14 and 15, a second substrate SUB2 may be bonded to a first substrate SUB1 by a sealing member SEAL, on which a thin-film transistor layer TFTL and an emission material layer EML are sequentially stacked. In some example embodiments, the sealing member SEAL may be formed on an interlayer dielectric layer INS of the thin-film transistor layer TFTL and a back connection electrode BCE, and a second substrate SUB2 on which a touch connection pad TSP is formed may be bonded by the sealing member SEAL.

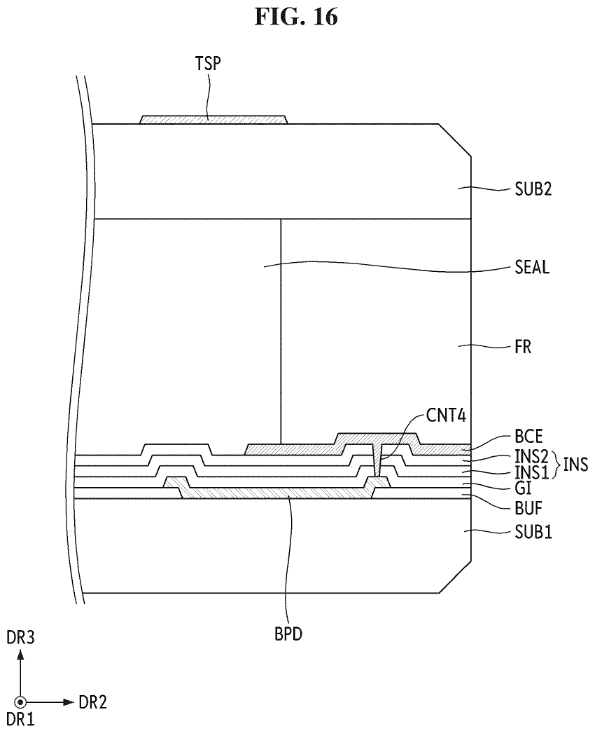

Subsequently, referring to FIG. 16, the empty space (or gap) on the outer side of the sealing member SEAL shown in FIG. 15 may be filled with a filling member FR, and the filling member FR may be cured. The filling member FR may include a thermosetting resin or a photocurable resin. The side surface of the filling member FR may be formed via a grinding process so that the side surface of the filling member FR coincides with or is flush with the outermost side of the first substrate SUB1, the outermost side of the thin-film transistor layer TFTL and the side surface of the second substrate SUB2, or the side surface of the filling member FR is located more to the inside than or is offset from the outermost side of the first substrate SUB1, the outermost side of the thin-film transistor layer TFTL and the side surface of the second substrate SUB2. Additionally, the corners of the first substrate SUB1 and the second substrate SUB2 may be chamfered during the grinding process.

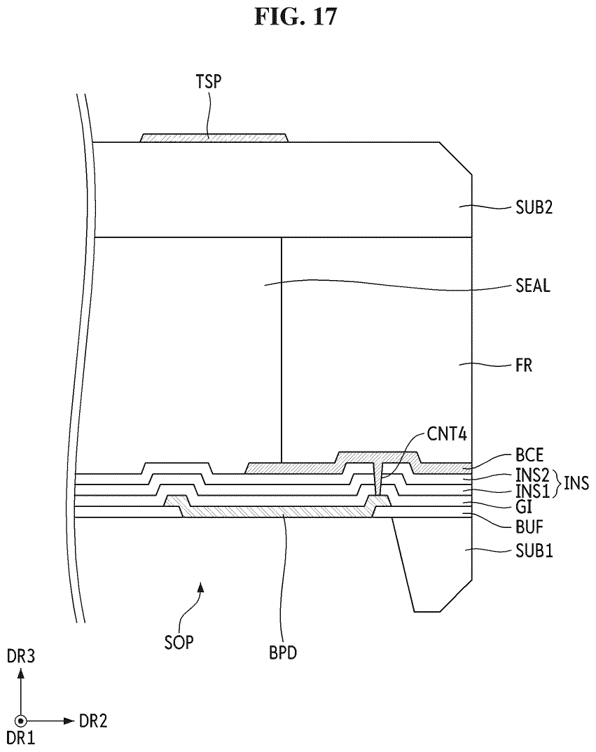

FIGS. 17 to 19 illustrate operations for fabricating a display device according to some example embodiments of the present disclosure.

Initially, referring to FIG. 17, an opening SOP penetrating the first substrate SUB1 may be formed via an etching process on the bottom of the display panel of FIG. 16, and the lower surface of the back connection pad BPD may be exposed by the opening SOP.

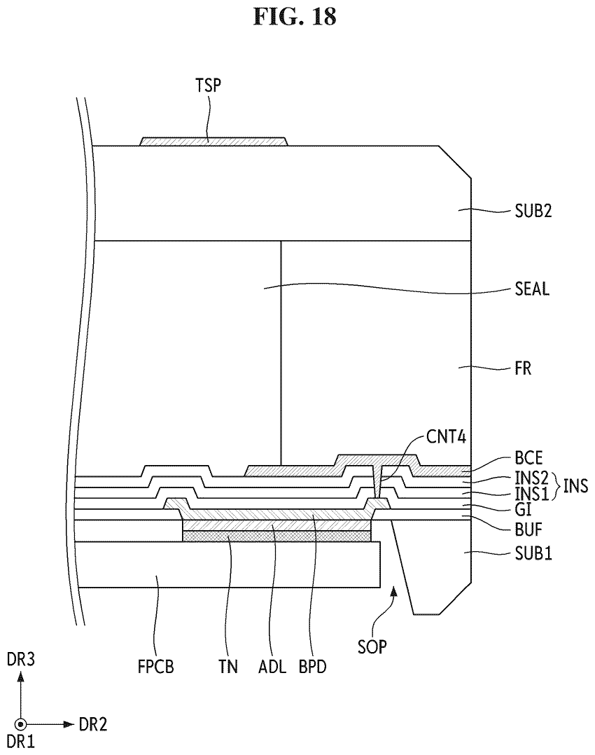

Referring to FIG. 18, a flexible printed circuit board FPCB is inserted into the opening SOP of the first substrate, and the back connection pad BPD exposed by the opening SOP may be bonded to a terminal TN of the flexible printed circuit board FPCB by an adhesive material ADL.

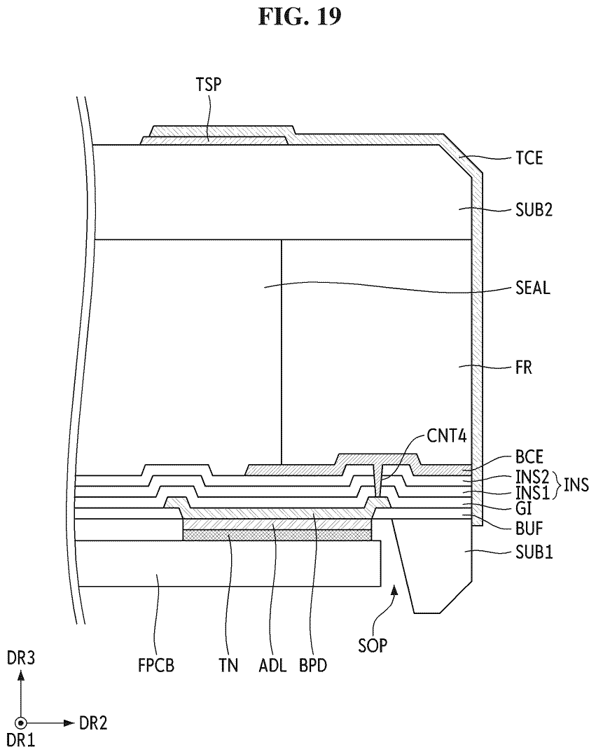

Referring to FIG. 19, a touch connection line TCE connecting a touch connection pad TSP with a back connection electrode BCE may be formed on the upper surface and a side surface of the display panel. In some example embodiments, the touch connection line TCE may be located on the touch connection pad TSP and the second substrate SUB2, and may be extended along the outermost sides of the filling member FR, the back connection electrode BCE of the thin-film transistor layer TFTL, the interlayer dielectric layer INS, the gate insulator GI and the buffer layer BUF so as to be further located on the outermost side of the first substrate SUB1.

The touch connection line TCE may be formed by a sputtering process, a transfer process, an ink screening process, etc. The sputtering process may include a masking process that forms a mask film having a plurality of exposure holes formed along a pattern of a plurality of touch connection lines TCE. The sputtering process may be a process that forms the touch connection line TCE through the exposure holes of the mask film by sputtering a conductive material to be used as the touch connection line TCE. The transfer process may be a process of transferring a plurality of conductive materials to be used as touch connection line TCE and molding them on one side of an elastic stamp, and then pressing it using a stamp to form the touch connection line TCE at a desired location. The ink screening process may be a process of forming a mask film having a plurality of exposure holes formed along a pattern of a plurality of touch connection lines TCE on the upper surface, side surfaces and lower surface of the display panel, and then applying a conductive ink onto the mask film, so that the conductive ink is formed at that location through the exposure holes to form touch connection line TCE.

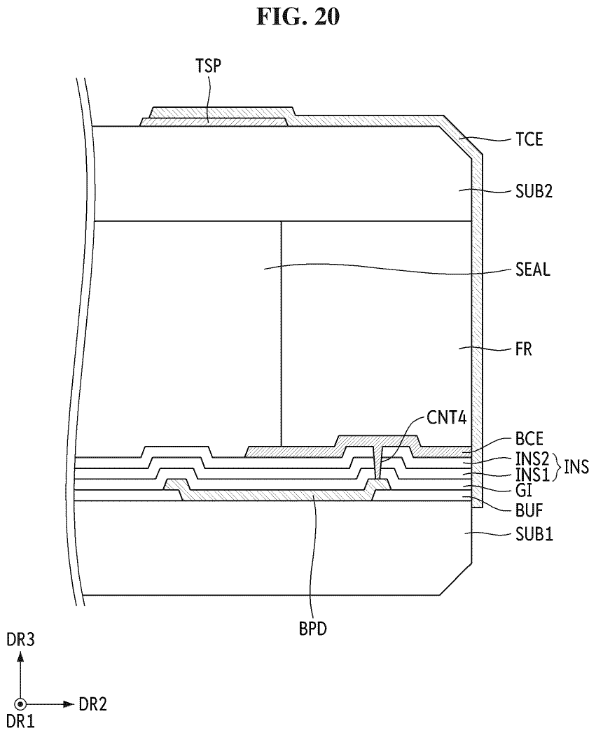

FIGS. 20 to 22 illustrate operations for fabricating display devices according to some example embodiments of the present disclosure.

The operation in FIGS. 20, 21, and 22 may be best understood with reference to FIGS. 17, 18, and 19 where like numerals indicate like elements not described again in detail.

Referring to FIGS. 20 to 22, with reference to FIGS. 17 to 19, a touch connection line TCE may be formed first, then an opening SOP of a first substrate SUB1 may be formed, and a printed circuit board FPCB may be inserted through the opening SOP.

By way of the processes of fabricating the display device shown in FIGS. 17 to 22, the process of forming a separate flexible printed circuit board that is directly connected to the touch connection pad TSP can be omitted, and the touch connection pad TSP and the back connection electrode BCE are connected through the touch connection line TCE to make electrical connection with the flexible printed circuit board FPCB located under the display panel via the back connection pad BPD, so that the fabrication process can be simplified and the fabricating time and cost can be saved.

The display device, according to some example embodiments, may be used in a variety of electronic devices. An electronic device, according to some example embodiments, includes the display device described above, and may further include a module or device having additional features in addition to the display device.

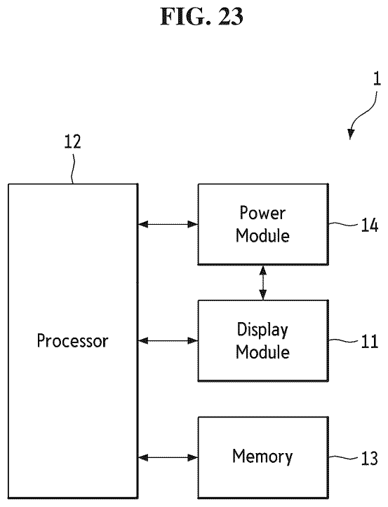

FIG. 23 is a block diagram of an electronic device according to some example embodiments of the present disclosure.

Referring to FIG. 23, an electronic device 1, according to some example embodiments of the present disclosure, may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information used for the operation of the processor 12 or the display module 11. When the processor 12 executes an application stored in the memory 13, an image data signal and/or an input control signal may be transmitted to the display module 11. The display module 11 may process the received signal and output image information through a display screen.

The power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to some example embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 1 instead of the display device.

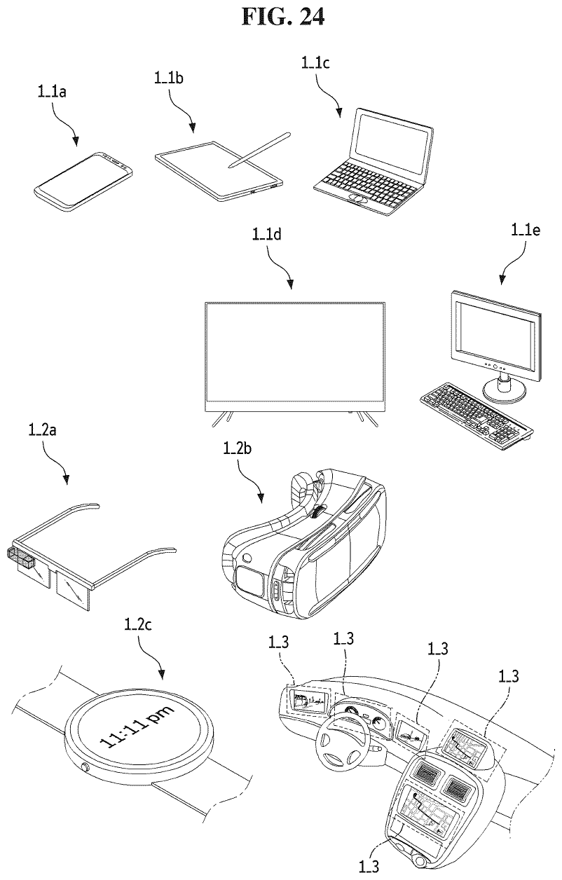

FIG. 24 illustrates different electronic devices including the display devices according to example embodiments of the present disclosure.

Referring to FIG. 24, the different electronic devices including or using display devices according to some example embodiments may include image display electronic devices such as a smart phone 1_1a, a tablet PC 1_1b, a laptop computer 1_1c, a TV 1_1d and a desktop monitor 1_1e, wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

Example embodiments are not necessarily mutually exclusive. For example, some example embodiments may include one or more features described with reference to one or more figures, and may also include one or more other features described with reference to one or more other figures.

As described herein, any devices, systems, modules, portions, units, controllers, circuits, and/or portions thereof according to any of the example embodiments, and/or any portions thereof (including, without limitation, the display module 11, the processor 12, the memory 13, the power module 14, the smart phone 1_1a, the tablet PC 1_1b, the laptop computer 1_1c, the TV 1_1d, the desktop monitor 1_1e, smart glasses 1_2a, the head-mounted display 1_2b, the smart watch 1_2c, and electronic devices for vehicles 1_3, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a System-on-Chip (SoC), a programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A display device comprising:
a first substrate comprising a display area and a non-display area;
a thin-film transistor layer on the first substrate, wherein the thin-film transistor layer comprises, an insulating layer on the first substrate and overlapping with the display area and the non-display area, and a first back connection electrode on the insulating layer and overlapping with the non-display area;
an emission material layer on the thin-film transistor layer and overlapping with the display area;
a filling member on the insulating layer of the thin-film transistor layer and the first back connection electrode and on an outer side of the emission material layer;
a second substrate on the emission material layer and the filling member;
a touch connection pad on the second substrate and overlapping with the non-display area; and
a touch connection line on the touch connection pad and the second substrate and extending along outermost sides of the second substrate, the filling member, and the thin-film transistor layer, the touch connection line being on an outermost side of the first substrate and overlapping with the first back connection electrode,
wherein the touch connection pad is electrically connected to the first back connection electrode through the touch connection line.

2. The display device of claim 1, wherein the outermost side of the filling member coincides with an outermost side of the first back connection electrode, and
wherein the touch connection line is in direct contact with the outermost side of the first back connection electrode.

3. The display device of claim 2, wherein the first substrate comprises an opening penetrating the first substrate,
wherein the thin-film transistor layer further comprises a back connection pad on the first substrate and overlapping with the non-display area and exposed through the opening, and
wherein the back connection pad is electrically connected to the first back connection electrode through a fourth contact hole penetrating the insulating layer.

4. The display device of claim 3, further comprising:
a flexible printed circuit board in the opening of the first substrate,
wherein the flexible printed circuit board is electrically connected to the back connection pad, and
wherein the touch connection pad is electrically connected to the flexible printed circuit board through the touch connection line, the first back connection electrode, and the back connection pad.

5. The display device of claim 3, wherein the touch connection line extends from the outermost side of the first substrate and is on a lower surface of the first substrate and a lower surface of the back connection pad exposed through the opening, and wherein the touch connection line is in direct contact with the back connection pad.

6. The display device of claim 5, wherein the insulating layer of the thin-film transistor layer comprises a groove that is recessed inwardly from the outermost side of the first back connection electrode,
wherein the touch connection line is on a lower surface of the first back connection electrode, an outermost side of the insulating layer and an upper surface of the first substrate defining the groove, and
wherein the touch connection line is in direct contact with the lower surface of the first back connection electrode.

7. The display device of claim 1, wherein the outermost side of the filling member is offset from an outermost side of the first back connection electrode, and
wherein the touch connection line is in direct contact with an upper surface and the outermost side of the first back connection electrode, the upper surface and the outermost side of the first back connection electrode being offset from the filling member.

8. The display device of claim 1, wherein the thin-film transistor layer further comprises a thin-film transistor overlapping with the display area and on the insulating layer, and a first connection electrode on the insulating layer and electrically connected to the thin-film transistor through a first contact hole overlapping with the display area and penetrating the insulating layer, and
wherein the first connection electrode and the first back connection electrode include a same material and the first connection electrode and the first back connection electrode are in a same layer.

9. The display device of claim 8, wherein the thin-film transistor layer further comprises:
a first via layer on the insulating layer and the first connection electrode,
a second connection electrode on the first via layer and electrically connected to the first connection electrode through a second contact hole penetrating the first via layer, and
a second back connection electrode between the first back connection electrode and the filling member and overlapping with the first back connection electrode,
wherein the second connection electrode and the second back connection electrode include a same material and are in a same layer.

10. The display device of claim 9, wherein the outermost side of the filling member coincides with an outermost side of the first back connection electrode and an outermost side of the second back connection electrode, and
wherein the touch connection line is in direct contact with the outermost side of the first back connection electrode and the outermost side of the second back connection electrode.

11. The display device of claim 8, wherein the thin-film transistor layer further comprises:
a first via layer on the insulating layer and the first connection electrode;
a second connection electrode on the first via layer and electrically connected to the first connection electrode through a second contact hole penetrating the first via layer;
a second via layer on the first via layer and the second connection electrode; and
a third back connection electrode between the first back connection electrode and the filling member and overlapping with the first back connection electrode,
wherein the emission material layer comprises an anode on the second via layer of the thin-film transistor layer and electrically connected to the second connection electrode through a third contact hole penetrating the second via layer, and
wherein the anode and the third back connection electrode include a same material and are in a same layer.

12. The display device of claim 11, wherein the outermost side of the filling member coincides with an outermost side of the first back connection electrode and an outermost side of the third back connection electrode, and
wherein the touch connection line is in direct contact with the outermost side of the first back connection electrode and the outermost side of the third back connection electrode.

13. A display device comprising:
a first substrate comprising a display area and a non-display area;
a thin-film transistor layer on the first substrate, wherein the thin-film transistor layer comprises, an insulating layer on the first substrate and overlapping with the display area and the non-display area, and a back connection electrode on the insulating layer and overlapping with the non-display area;
an emission material layer on the thin-film transistor layer and overlapping with the display area;
a filling member on the insulating layer of the thin-film transistor layer and the back connection electrode and on an outer side of the emission material layer;
a second substrate on the emission material layer and the filling member;
a touch connection pad on the second substrate and overlapping with the non-display area; and
a touch connection line on the touch connection pad and the second substrate, and on outermost sides of the second substrate, the filling member, and the thin-film transistor layer, the touch connection line overlapping with the back connection electrode,
wherein the touch connection pad is electrically connected to the back connection electrode through the touch connection line.

14. The display device of claim 13, wherein the outermost side of the filling member coincides with an outermost side of the back connection electrode, and
wherein the touch connection line is in direct contact with the outermost side of the back connection electrode.

15. The display device of claim 14, wherein the first substrate comprises an opening penetrating the first substrate, wherein the thin-film transistor layer further comprises a back connection pad on the first substrate, overlapping with the non-display area and exposed through the opening, and
wherein the back connection pad is electrically connected to the back connection electrode through a fourth contact hole penetrating the insulating layer.

16. The display device of claim 15, further comprising:
a flexible printed circuit board in the opening of the first substrate,
wherein the flexible printed circuit board is electrically connected to the back connection pad, and
wherein the touch connection pad is electrically connected to the flexible printed circuit board through the touch connection line, the back connection electrode, and the back connection pad.

17. The display device of claim 15, wherein a portion of a lower surface of the insulating layer of the thin-film transistor layer is exposed by the opening, and
wherein the touch connection line is on the lower surface of the insulating layer exposed by the opening and a lower surface of the back connection pad, and the touch connection line is in direct contact with the lower surface of the back connection pad.

18. The display device of claim 17, wherein the insulating layer of the thin-film transistor layer comprises a groove that is recessed inwardly from the outermost side of the back connection electrode,
wherein the touch connection line is on the lower surface of the back connection electrode and an outermost side of the insulating layer defining the groove, and
wherein the touch connection line is in direct contact with the lower surface of the back connection electrode.

19. The display device of claim 13, wherein the thin-film transistor layer further comprises
a thin-film transistor overlapping with the display area and on the insulating layer, and
a first connection electrode on the insulating layer and electrically connected to the thin-film transistor through a first contact hole overlapping with the display area and penetrating the insulating layer, and
wherein the first connection electrode and the back connection electrode include a same material and are in a same layer.

20. An electronic device comprising:
a display device configured to display an image; and
a processor configured to transmit an image data signal to the display device, the image data signal being configured to display the image, and wherein the display device comprises,
a first substrate comprising a display area and a non-display area;
a thin-film transistor layer on the first substrate, wherein the thin-film transistor layer comprises, an insulating layer on the first substrate and overlapping with the display area and the non-display area, and a first back connection electrode on the insulating layer and overlapping with the non-display area;
an emission material layer on the thin-film transistor layer and overlapping with the display area;
a filling member on the insulating layer of the thin-film transistor layer and the first back connection electrode and on an outer side of the emission material layer;
a second substrate on the emission material layer and the filling member;
a touch connection pad on the second substrate and overlapping with the non-display area; and
a touch connection line on the touch connection pad and the second substrate and extending along outermost sides of the second substrate, the filling member, and the thin-film transistor layer and being on an outermost side of the first substrate and overlapping with the first back connection electrode,
wherein the touch connection pad is electrically connected to the first back connection electrode through the touch connection line.
